(19) United States
(12) Patent Application Publication
(10) Pub. No.: US 2006/0051888 A1
(43) Pub. Date: Mar. 9, 2006

(54) Method of fabricating organic light emitting display and display fabricated by the method

(76) Inventors: Jae-Bon Koo, Yongin-si (KR); Min-Chul Suh, Seongnam-si (KR)

Correspondence Address: H.C. PARK & ASSOCIATES, PLC, 8500 LEESBURG PIKE, SUITE 7500, VIENNA, VA, 22182, US

(21) Appl. No.: 11/151,277

(22) Filed: Jun. 14, 2005

(30) Foreign Application Priority Data
Jun. 29, 2004 (KR) 2004-49819

(51) Int. Cl. H01L 51/40

(52) U.S. Cl. 438/99

(57) ABSTRACT

The present invention provides a method of fabricating an improved organic light emitting display (OLED) as well as an OLED fabricated by the method. The method may include the following steps, which may be performed in any suitable order. At a first step, a substrate having at least one cell region is provided. At a second step, a light emitting device portion having at least one light emitting device is formed on the cell region. At a third step, a passivation layer is formed on the light emitting device portion. At a fourth step, a thin film transistor (TFT) portion is formed on the passivation layer. The TFT portion has an organic TFT (OTFT) electrically connected to each of the light emitting devices.

### CROSS-REFERENCE TO RELATED APPLICATIONS

This application claims priority to Korean Patent Application No. 10-2004-0049819, filed Jun. 29, 2004, the disclosure of which is incorporated herein by reference in its entirety.

### BACKGROUND OF THE INVENTION

1. Field of the Invention

The present invention relates generally to methods of fabricating organic light emitting displays (OLEDs) and to OLEDs so fabricated and, more particularly, to a method of fabricating an OLED having an organic thin film transistor (OTFT) and to an OLED fabricated by the method of the invertion.

2. Description of the Related Art

Organic thin film transistors (OTFTs) occupy the field of organic semiconductor devices and may soon replace conventional inorganic TFTs. The OTFT has the electrical and optical properties of a semiconductor as well as one or more unique physical properties, and may be fabricated using economical process technology that includes, but is not limited to, printing methods. Thus, large surface-area devices may be inexpensively produced, and such devices may be formed on flexible substrates, such as plastic substrates. Accordingly, a new product group of semiconductor devices, for example, flexible electronic devices, may be created.

The OTFT may be used in an organic light emitting display (OLED) to produce an active matrix (AM) TFT OLED.

OLEDs are quite appropriate for a medium of any size that displays moving wide viewing angle, low power consumption, and are emissive displays. Also, OLEDs can be fabricated at low temperature using simple processes evolved from conventional semiconductor manufacturing technology. For these reasons, OLEDs have been hailed as the next-generation flat panel display (FPD).

The semiconductor layer in an OTFT has a low mobility. To increase an on-current level, the OTFT is manufactured to be larger than a comparable inorganic TFT. However, as the size of a TFT in a display increases, the area of a region occupied by a pixel electrode in a unit pixel decreases. As a result, an aperture ratio of the display is reduced.

One approach to overcoming this drawback is provided in Korean Patent No. 2003-0017748 which discloses on “Organic Light Emitting Device in which Organic Field Effect Transistor and Organic Light Emitting Diode are Combined and Method of Fabricating the Same.” In this disclosure, an OTFT is vertically formed on an organic light emitting device. However, this vertical structure includes an insulating layer, which is partially disposed between the OTFT and the organic light emitting device. Thus, after the organic light emitting device is fabricated, a side portion of the organic light emitting device disposed under the OTFT may be damaged during a spin coating process or a cleaning process, thereby degrading the stability of the display.

### SUMMARY OF THE INVENTION

The present invention, therefore, solves the aforementioned problems associated with conventional displays and manufacturing methods by providing a method of fabricating an organic light emitting display (OLED), and an OLED fabricated by the method in which an organic light emitting device is protected during the formation of an organic thin film transistor (OTFT) by forming a passivation layer.

Also, the present invention provides a method of fabricating an OLED having an OTFT in which an organic passivation layer is formed on both front and side surfaces of a substrate to improve the stability of subsequent processes, as well as an OLED fabricated by this method.

In an exemplary embodiment of the present invention, a method of fabricating an improved OLED may include the following steps, which may be performed in any suitable order. At a first step, a substrate having at least one cell region is provided. At a second step, a light emitting device portion having at least one light emitting device on the cell region is provided. At a third step, a passivation layer on the light emitting device portion is provided. At a fourth step, a TFT portion on the passivation layer is formed. The TFT portion may include an OTFT electrically connected to each of the light emitting devices. At a fifth step, a passivation layer may be formed on a side portion of the light emitting device portion, on a side surface of the substrate, or on a bottom surface of the substrate. The passivation layer may be one of an organic passivation layer, an inorganic passivation layer, and a double layer thereof.

The organic passivation layer may be a parylene layer, formed using a chemical vapor deposition (CVD) method, to a thickness of about 1000 Å to 1 about μm.

Steps associated with forming the light emitting device may include the following. At a first step, forming a lower electrode on the cell region is formed. At a second step, an organic layer having an emission layer (EML) is formed on the lower electrode. At a third step, an upper electrode is formed on the organic layer. The upper electrode may be formed as either an anode or a cathode. The upper electrode may be either a single layer of reflective material or a double layer comprised of a transparent material backed with a reflective material.

Additionally, forming the OTFT may include the following steps, which may be performed in any suitable order. At a first step, source electrode and a drain electrode are formed on the passivation layer to be spaced apart from each other. At a second step, an organic semiconductor layer is formed between the source and drain electrodes such that the organic semiconductor layer is connected to the source and drain electrodes. At a third step, a gate insulating layer is formed on the organic semiconductor layer. At a fourth step, a gate electrode is formed on the gate insulating layer. Additionally, before the organic thin film transistor, is formed a contact hole may be formed in the passivation layer such that the light emitting device is exposed, and the drain electrode may be electrically connected to the light emitting device through the contact hole.

The organic semiconductor layer may be formed of a material selected from a group consisting of pentacene, tetracene, rubrene, α-hexathienylene, poly(3-hexylthiophene-2, 5-diyl), poly(thienylene vinylene), C60, NTCDA, PTCDA, and F16CuPc.

The OTFT may be one of a PMOS transistor and an NMOS transistor.

The substrate may be made from any suitable. Such as a material selected from a group consisting of glass, a quartz, and plastic.

In another exemplary embodiment of the present invention, an OLED may include a substrate. A light emitting device portion may be disposed on the substrate and include at least one light emitting device. A passivation layer may be disposed on the light emitting device portion. A TFT portion may be disposed on the passivation layer and include an OTFT electrically connected to each of the light emitting devices.

The passivation layer may be disposed on a side portion of the light emitting device portion, on a side surface of the substrate, or on a bottom surface of the substrate, and may.

The passivation layer may be one selected from a group consisting of an organic passivation layer, an inorganic passivation layer, and a double layer thereof.

The passivation layer may be a parylene layer, having a thickness of about 1000 Å to about 1 μm.

The light emitting device may include a lower electrode disposed on the substrate. An upper electrode may be disposed on the lower electrode. An organic layer may be interposed between the upper and lower electrodes and include an emission layer (EML).

The OTFT may include a source electrode and a drain electrode disposed on the passivation layer and spaced apart from each other. An organic semiconductor layer may be interposed between the source and drain electrodes and electrically connected to the source and drain electrodes. A gate insulating layer may be disposed on the organic semiconductor layer. A gate electrode may be disposed on the gate insulating layer and overlap the organic semiconductor layer. The drain electrode may be electrically connected to the light emitting device by penetrating the passivation layer.

### BRIEF DESCRIPTION OF THE DRAWINGS

The above and other features of the present invention will be described in reference to certain exemplary embodiments thereof with reference to the attached drawings.

FIG. 1 is a plan view of a substrate including a plurality of organic light emitting displays (OLEDs).

FIGS. 2A and 3A are cross-sectional views taken along the line I-I′ of FIG. 1, which illustrate a method of fabricating an OLED according to an exemplary embodiment of the present invention.

FIGS. 2B and 3B are enlarged cross-sectional views illustrating portions P of FIGS. 2A and 3A, respectively.

FIGS. 4A and 4B are cross-sectional views of an OLED according to an exemplary embodiment of the present invention.

### DETAILED DESCRIPTION

The present invention will now be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure is thorough and complete and fully conveys the scope of the invention to those skilled in the art. The thicknesses of layers or regions shown in the drawings are exaggerated for clarity. The same reference numerals are used to denote the same elements throughout the specification.

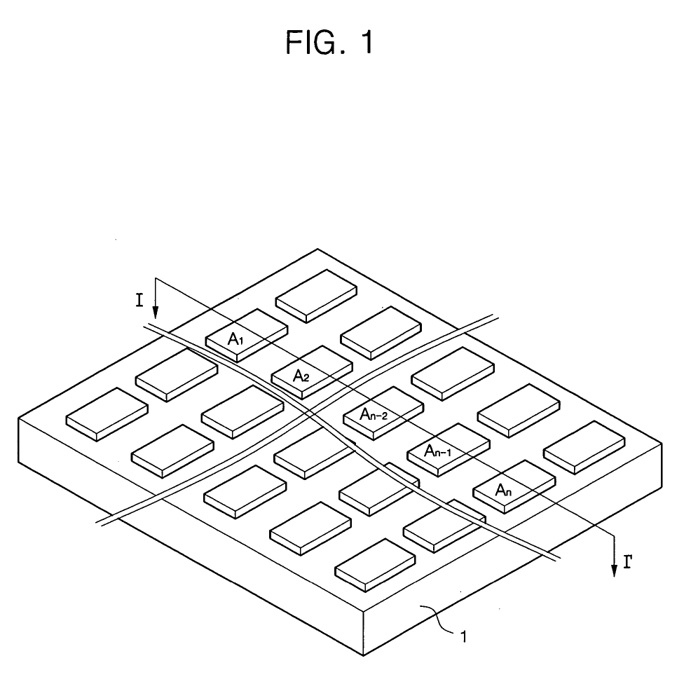

FIG. 1 is a plan view of a substrate including a plurality of organic light emitting displays (OLEDs). Referring to FIG. 1, at least one cell region A1, A2, . . . , and Aₙ is disposed on a substrate 1. Each of the cell regions A1, A2, . . . , and Aₙ is a region where a single OLED is disposed. A light emitting device portion including at least one light emitting device is formed on each of the cell regions A1, A2, . . . , and Aₙ, and a passivation layer is formed on the light emitting device portion. The passivation layer may be further formed on a side portion of the light emitting device portion. Also, a thin film transistor (TFT) portion, which includes an organic TFT (OTFT) electrically connected to each of the light emitting devices, is disposed on the passivation layer. The substrate 1 is cut into the respective cell regions A1, A2, . . . , and Aₙ, and a process for surface-treating the section of each of the cell regions A1, A2, . . . , and Aₙ is performed, thereby completing a single OLED. Each of the OLEDs has interconnections including a plurality of gate lines and a plurality of data lines. In each unit pixel, an OTFT, a capacitor, and an organic light emitting device, which are connected to the interconnections, are disposed. Also, the gate lines and the data lines are connected to an external driving integrated circuit (IC) so that they drive the organic light emitting device of the unit pixel in response to a signal.

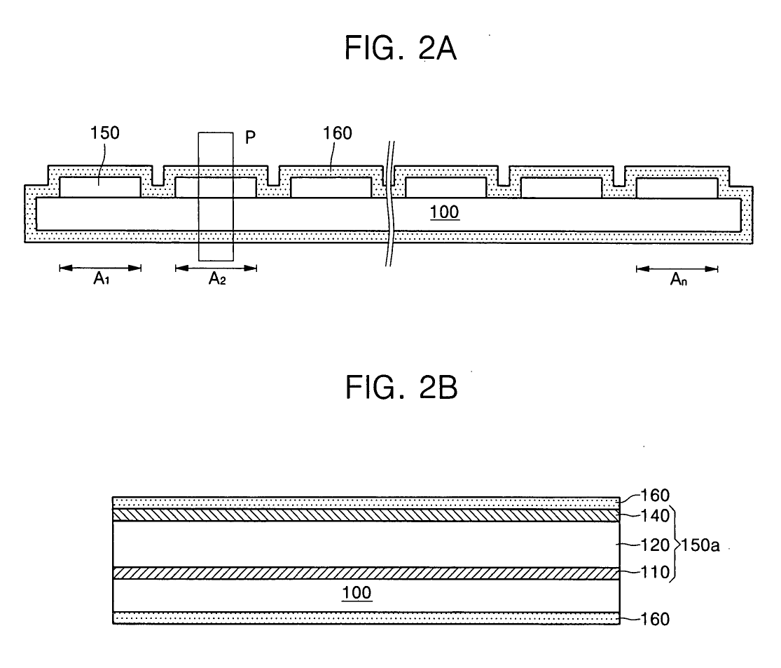

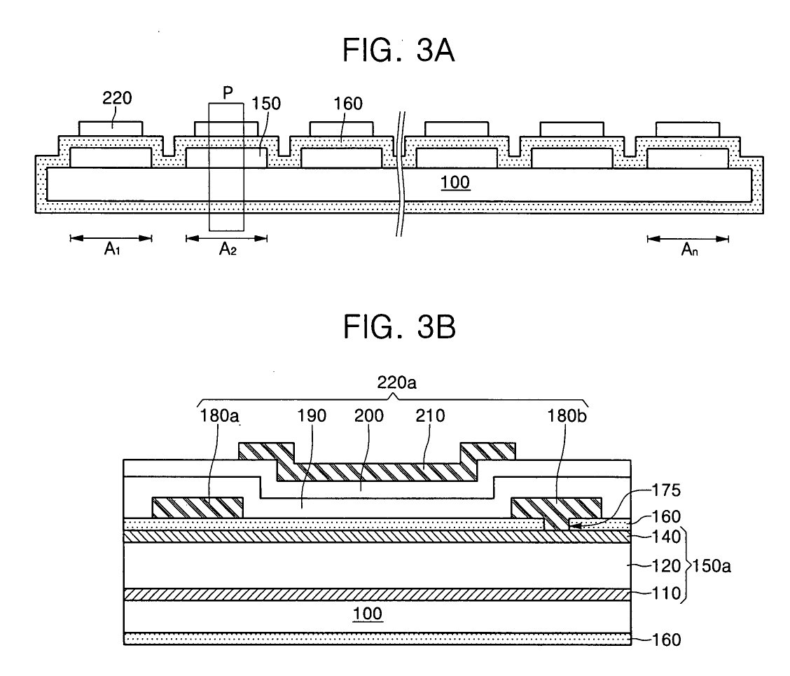

FIGS. 2A and 3A are cross-sectional views taken along the line I-I′ of FIG. 1. Each illustrates a separate method of fabricating an OLED according to an exemplary embodiment of the present invention. FIG. 2B is an enlarged cross-sectional view illustrating portion P of FIG. 2A. Similarly, FIG. 3B is an enlarged cross-sectional view illustrating portion P of FIG. 3A.

Referring to FIG. 2A, a light emitting device portion 150 that includes at least one organic light emitting device is formed on a substrate 100 that has at least one cell region Aₙ. A passivation layer 160 is formed on the light emitting device portion 150. The passivation layer 160 may be further formed on a side portion of the light emitting device portion 150. The substrate 100 may comprise any suitable material. Such as one selected from the group consisting of a glass, a quartz, and plastic.

FIG. 2B illustrates a detailed structure of the portion P of the cell region Aₙ.

Referring to FIGS. 2A and 2B, a lower electrode 110 of a unit pixel in the light emitting device portion 150 is formed on the substrate 100. Also, an organic layer 120 including an emission layer (EML) is formed on the lower electrode 110.

The organic layer 120 may be formed of at least one layer selected from the group consisting of an emitting layer (EML), an electron injection layer (EIL), a hole blocking layer, a hole transport layer (HTL), and a hole injection layer (HIL).

An upper electrode 140 is formed on the organic layer 120. The upper electrode 140 may comprise a single reflective material or a double layer of a transparent material backed with a reflective material. Thus, the upper electrode 140 reflects light emitted from the organic layer 120 so that the light is emitted toward the substrate 100. Also, when the upper electrode 140 is an anode, the lower electrode 110 may be a cathode. Inversely, when the upper electrode 140 is a cathode, the lower electrode 110 may be an anode.

Accordingly, the lower electrode 110, the organic layer 120, and the upper electrode 140 are formed on the substrate 100, thereby completing an organic light emitting device 150a. In this or a similar manner a light emitting device portion (150 in FIG. 2A) having at least one organic light emitting device 150a per unit pixel may be produced.

As shown in FIG. 2A, the passivation layer 160 is also formed on the substrate 100 where the organic light emitting device 150a is formed, i.e., on the light emitting device portion 150. However, because FIG. 2B is an enlarged cross-sectional view of the portion P of FIG. 2A, FIG. 2B only shows the passivation layer 160 formed on the organic light emitting device 150a.

The passivation layer 160 may be produced any suitable using chemical vapor deposition (CVD) technique(s) selected from the group consisting of low pressure CVD (LPCVD), plasma-enhanced CVD (PECVD), and atmospheric pressure CVD (APCVD). The passivation layer 160 may be formed to a thickness of about 1000 Å to about 1 μm such that the stress of the passivation layer 160 does not affect the organic light emitting device 150a.

The passivation layer 160 may be formed on a side surface or a bottom surface of the substrate 100. The passivation layer 160 may be an organic passivation layer, an inorganic passivation layer, or a double layer thereof, and the organic passivation layer may be formed of parylene.

Since a parylene derivative has high hydrophobic properties, solvent resistance properties, and chemical resistance properties, it may be used to protect the organic light emitting device 150a from solvents and etchants during a developing process for a photolithography process or a stripping process, that may be subsequently performed after the organic light emitting device 150a is fabricated. Also, the passivation layer 160 may be formed on top and side surfaces of the light emitting device portion 150, so that both the top and side portions of the organic light emitting device 150a are protected from the solvents and etchants.

The parylene layer can be easily made into a thin film on a substrate at normal temperature using a vapor deposition method, remains stable with light of wavelength 300 nm or less, and can be etched by a reactive ion beam etch (RIE) process. In addition, the parylene layer can be uniformly coated even on fine pinholes and cracks irrespective of shapes of an object to be coated and has excellent insulating properties. Therefore, the parylene layer can reliably protect the organic light emitting device 150a during subsequent fabrication processes.

Referring to FIG. 3A, a TFT portion 220 is formed on the passivation layer 160 to correspond to each of the cell regions Aₙ. The formation of the TFT portion 220 includes formation of an OTFT that is electrically connected to each of the light emitting device portions 150.

FIG. 3B illustrates a detailed structure of a portion P of the cell region Aₙ where the TFT portion 220 is formed. Referring to FIG. 3B, a contact hole 175 is formed in the passivation layer 160 to expose a portion of the organic light emitting device 150a. Specifically, a portion of the upper electrode 140 of the organic light emitting device 150a is exposed by the contact hole 175. The contact hole 175 may be obtained using laser ablation (LAT).

A drain electrode 180b is formed on the passivation layer 160 where the contact hole 175 is formed, to be in contact with the upper electrode 140 of the organic light emitting device 150a. Thus, the drain electrode 180b is electrically connected to the organic light emitting device 150a. During the formation of the drain electrode 180b, a source electrode 180a may be patterned at the same time. Also, the source and drain electrodes 180a and 180b may be obtained by performing deposition and patterning simultaneously through a deposition method using a shadow mask or an inkjet printing method.

Thus, owing to the organic passivation layer 160, the organic light emitting device 150a can be protected from solvents and etchants during the process of patterning the electrodes 180a and 180b of the OTFT. Hence, the OTFT can be stably fabricated without damaging the organic light emitting device 150a.

Between the source and drain electrodes 180a and 180b, an organic semiconductor layer 190 may be formed such that it contacts the source and drain electrodes 180a and 180b.

The organic semiconductor layer 190 may be a p-type semiconductor layer, formed of a material selected from the group consisting of α-hexathienylene, DH-alpha-6T, and pentacene.

Alternatively, the organic semiconductor layer 190 may be an n-type semiconductor layer, formed of a material selected from the group consisting of pentacene, tetracene, rubrene, poly(thienylene vinylene), poly(3-hexylthiophene-2, 5-diyl), C60, NTCDA, PTCDA, and F16CuPc.

A gate insulating layer 200 is formed on the organic semiconductor layer 190. The gate insulating layer 200 may be formed of a typical insulating material, for example, silicon oxide (SiO₂) or silicon nitride (SiNₓ), or formed of a ferroelectric insulating material to lower a threshold voltage. However, since the above-described materials are deposited at high temperature, the organic semiconductor layer 190 and the organic light emitting device 150a may be damaged during the deposition process. Therefore, the gate insulating layer 200 is preferably formed of an organic insulating layer.

A gate electrode 210 is formed on the gate insulating layer 200. The gate electrode 210 may be formed of any suitable material such as one selected from the group consisting of Al, AlNd, Cr, Al/Cu, Au/Ti, Au/Cr, and MoW, but the present invention is not limited thereto. For example, the gate electrode 210 may be formed of a conductive polymer. It is also possible to form the gate electrode 210 by depositing and patterning a metal layer. However, in order to protect the underlying organic layers, the gate electrode 210 may be deposited using a shadow mask or an inkjet printing method. In such a process, the source electrode 180a, the drain electrode 180b, the organic semiconductor layer 190, the gate insulating layer 200, and the gate electrode 210 are formed, thereby completing an OTFT 220a. The OTFT 220a may be an NMOS transistor or a PMOS transistor according to the type of the organic semiconductor layer 190. The result of the process produces a TFT portion (220 of FIG. 3A), having an OTFT 220a electrically connected to each of the organic light emitting devices 150a.

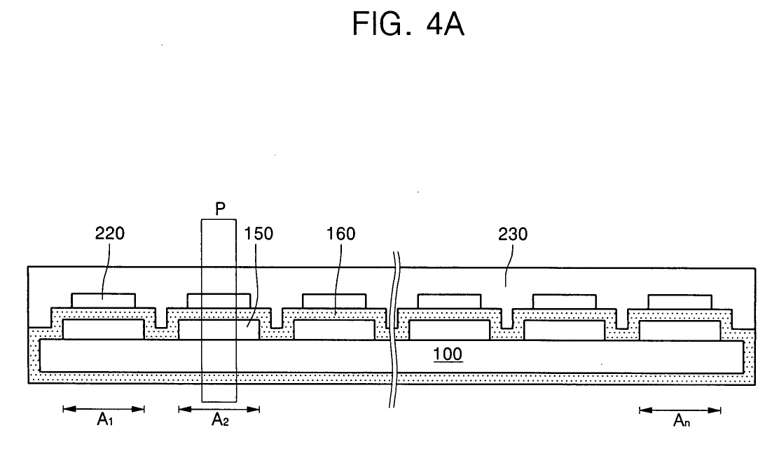

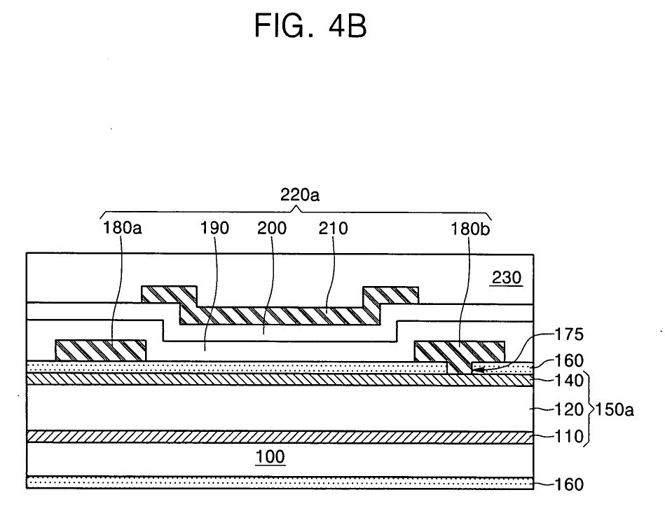

Hereinafter, the structure of an OLED according to an exemplary embodiment of the present invention will be described with reference to FIGS. 4A and 4B.

Referring to FIGS. 4A and 4B, a passivation layer 230 is stacked on the TFT portion 220, and the resultant structure is encapsulated and cut into the cell regions Aₙ, thereby completing the respective OLEDs.

A light emitting device portion 150 and the TFT portion 220, which is electrically connected to the light emitting device portion 150, are disposed on a substrate 100, and each pair of the light emitting device portion 150 and the TFT portion 220 constitutes a unit pixel P.

A passivation layer 160 is formed on the light emitting device portion 150. The passivation layer 160 may be formed on a side surface or a bottom surface of the substrate 100. The passivation layer 160 may be an organic passivation layer, an inorganic passivation layer, or a double layer thereof, and the organic passivation layer may be a parylene layer. Also, the passivation layer 160 may be formed to a thickness of about 1000 Å thick or more.

The TFT portion 220 is disposed on the passivation layer 160 and includes an OTFT. Interconnections including a plurality of gate lines and a plurality of data lines are disposed in the TFT portion 220. The OTFT and a capacitor, which are connected to the interconnections, are disposed in and connected to the underlying light emitting device portion 150.

The passivation layer 160 protects an organic light emitting device from solvents and etchants during a developing process such as, but not limited to, a photolithography process or a stripping process, either of which may be performed during the fabrication of devices of the TFT portion 220. Thus, the devices of the TFT portion 220 can be stably formed without damaging the organic light emitting device.

The substrate 100 may comprise a material selected from the group consisting of a glass, quartz, and plastic.

FIG. 4B illustrates an OTFT 220a and organic light emitting device 150a of a unit pixel P of the OLED of FIG. 4A.

Specifically, the organic light emitting device 150a is disposed on a substrate 100, and a passivation layer 160 is disposed thereon. The organic light emitting device 150a includes a lower electrode 110 disposed on the substrate 100, an upper electrode 140 disposed on the lower electrode 110, and an organic layer 120, which is interposed between the upper and lower electrodes 140 and 110 and has an EML. The organic layer 120 may further include at least one layer selected from the group consisting of an EIL, a hole blocking layer, a HTL, and a HIL.

The upper electrode 140 may be an anode or a cathode. Structurally the upper electrode 140 may be a single reflective electrode or a double layered electrode formed of a transparent material backed with a reflective material. Thus, the upper electrode 140 reflects light emitted from the organic layer 120 such that the light is emitted toward the substrate 100.

The passivation layer 160 may be formed on a bottom surface of the substrate 100. Also, the passivation layer 160 may be a single or double layer of organic or inorganic materials. For example, the passivation layer 160 may be a single layer formed of parylene, or a double layer formed of a parylene layer and an inorganic passivation layer. The passivation layer 160 may be formed to a thickness of about 1000 Å to about 1 μm such that the stress of the passivation layer 160 does not affect the organic light emitting device 150a.

The OTFT 220a is disposed on the passivation layer 160. The OTFT 220a includes a source electrode 180a and a drain electrode 180b, which are disposed on the passivation layer 160 and spaced apart from each other, and an organic semiconductor layer 190, which is interposed between the source and drain electrodes 180a and 180b and connected to the source and drain electrodes 180a and 180b. The drain electrode 180b may be electrically connected to the organic light emitting device 150a by penetrating the passivation layer 160.

The organic semiconductor layer 190 may be a p-type semiconductor layer, which is formed of a material selected from the group consisting of a-hexathienylene, DH-alpha-6T, and pentacene. Alternatively, the organic semiconductor layer 190 may be an n-type semiconductor layer, which is formed of a material selected from the group consisting of pentacene, tetracene, rubrene, poly(thienylene vinylene), poly(3-hexylthiophene-2, 5-diyl), C60, NTCDA, PTCDA, and F16CuPc.

A gate insulating layer 200 is disposed on the organic semiconductor layer 190, and a gate electrode 210 is disposed on the gate insulating layer 200 to overlap the organic semiconductor layer 190.

The gate insulating layer 200 may be formed of a typical insulating material, for example, silicon oxide (SiO₂) or silicon nitride (SiNₓ), or formed of a ferroelectric insulating material to drop a threshold voltage. However, since the above-described materials are deposited at high temperature, the organic semiconductor layer 190 and the organic light emitting device 150a may be damaged during the deposition process. Therefore, the gate insulating layer 200 is preferably an organic insulating layer.

The gate electrode 210 may be formed of any suitable material including but not limited to a material selected from the group consisting of Al, AlNd, Cr, Al/Cu, Au/Ti, Au/Cr, and MoW. For example, the gate electrode 210 may also be formed of a conductive polymer.

To complete the fabrication process, the source electrode 180a, the drain electrode 180b, the organic semiconductor layer 190, the gate insulating layer 200, and the gate electrode 210 are formed, thereby completing a finished OTFT 220a of the unit pixel P. The OTFT 220a may be an NMOS transistor or a PMOS transistor depending on the type of organic semiconductor layer 190 used.

In the exemplary embodiments of the present invention as described above, a passivation layer is formed to protect an organic light emitting device during the entire fabricating process. Thus, the organic light emitting device can be reliably protected during the fabrication of an OTFT and subsequent processes.

Further, an organic passivation layer can be uniformly coated even on fine pinholes and cracks and has excellent insulation properties and high hydrophobic properties, solvent resistance properties, and chemical resistance properties. By using this organic passivation layer, an OLED can be fabricated in a more stable manner, thereby increasing production yield.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

1. A method of fabricating an organic light emitting display comprising:
providing a substrate having at least one cell region;
forming a light emitting device portion on the cell region, the light emitting device portion having at least one light emitting device;
forming a passivation layer on the light emitting device portion; and
forming a thin film transistor portion on the passivation layer, the thin film transistor portion having an organic thin film transistor electrically connected to each of the light emitting devices.

2. The method of claim 1, wherein forming the passivation layer comprises forming the passivation layer on a side portion of the light emitting device portion.

3. The method of claim 1, wherein forming the passivation layer comprises forming the passivation layer on a side surface of the substrate.

4. The method of claim 1, wherein forming the passivation layer comprises forming the passivation layer on a bottom surface of the substrate.

5. The method of claim 1, wherein the passivation layer is selected from a group consisting of an organic passivation layer, an inorganic passivation layer, and a double layer thereof.

6. The method of claim 5, wherein the organic passivation layer is a parylene layer.

7. The method of claim 6, wherein the parylene layer is formed by a chemical vapor deposition method.

8. The method of claim 1, wherein the passivation layer is formed to a thickness of about 1000 Å to about 1 μm.

9. The method of claim 1, wherein forming the light emitting device comprises:
forming a lower electrode on the cell region;
forming an organic layer having an emission layer on the lower electrode; and
forming an upper electrode on the organic layer.

10. The method of claim 9, wherein the upper electrode is formed as one of an anode and a cathode.

11. The method of claim 9, wherein the upper electrode is one of a reflective electrode and a double layer of a transparent electrode and a reflective layer.

12. The method of claim 1, wherein forming the organic thin film transistor comprises:
forming a source electrode and a drain electrode on the passivation layer to be spaced apart from each other;
forming an organic semiconductor layer between the source electrode and the drain electrode to be connected to the source electrode and the drain electrode;
forming a gate insulating layer on the organic semiconductor layer; and
forming a gate electrode on the gate insulating layer.

13. The method of claim 12, further comprising, before the formation of the organic thin film transistor, forming a contact hole in the passivation layer to expose the light emitting device,
wherein the drain electrode is electrically connected to the light emitting device through the contact hole.

14. The method of claim 12, wherein the organic semiconductor layer is formed of a material selected from a group consisting of pentacene, tetracene, rubrene, α-hexathienylene, poly(3-hexylthiophene-2, 5-diyl), poly(thienylene vinylene), C60, NTCDA, PTCDA, and F16CuPc.

15. The method of claim 1, wherein the organic thin film transistor is one of a PMOS transistor and an NMOS transistor.

16. The method of claim 1, wherein the substrate is one selected from a group consisting of a glass substrate, a quartz substrate, and a plastic substrate.

17. An organic light emitting display, comprising:
a substrate;
a light emitting device portion disposed on the substrate and having at least one light emitting device;
a passivation layer disposed on the light emitting device portion; and
a thin film transistor portion disposed on the passivation layer and having an organic thin film transistor electrically connected to each of the light emitting devices.

18. The display of claim 17, wherein the passivation layer is disposed on a side portion of the light emitting device portion.

19. The display of claim 17, wherein the passivation layer is disposed on a side surface of the substrate.

20. The display of claim 17, wherein the passivation layer is disposed on a bottom surface of the substrate.

21. The display of claim 17, wherein the passivation layer is one selected from a group consisting of an organic passivation layer, an inorganic passivation layer, and a double layer thereof.

22. The display of claim 21, wherein the organic passivation layer is a parylene layer.

23. The display of claim 17, wherein the passivation layer has a thickness of about 1000 Å to about 1 μm.

24. The display of claim 17, wherein the light emitting device comprises:
a lower electrode disposed on the substrate;
an upper electrode disposed on the lower electrode; and
an organic layer interposed between the upper electrode and the lower electrode and having an emission layer.

25. The display of claim 24, wherein the upper electrode is one of an anode and a cathode.

26. The display of claim 24, wherein the upper electrode is one of a reflective electrode and a double layer of a transparent electrode and a reflective layer.

27. The display of claim 17, wherein the organic thin film transistor comprises:
a source electrode and a drain electrode disposed on the passivation layer and spaced apart from each other;
an organic semiconductor layer interposed between the source electrode and the drain electrode and electrically connected to the source electrode and the drain electrode;
a gate insulating layer disposed on the organic semiconductor layer; and
a gate electrode disposed on the gate insulating layer and overlapping the organic semiconductor layer.

28. The display of claim 27, wherein the drain electrode is electrically connected to the light emitting device by penetrating the passivation layer.

29. The display of claim 27, wherein the organic semiconductor layer is formed of a material selected from a group consisting of pentacene, tetracene, rubrene, α-hexathienylene, poly(3-hexylthiophene-2, 5-diyl), poly(thienylene vinylene), C60, NTCDA, PTCDA, and F16CuPc.

30. The display of claim 17, wherein the organic thin film transistor is one of a PMOS transistor and an NMOS transistor.

31. The display of claim 17, wherein the substrate is one selected from a group consisting of a glass substrate, a quartz substrate, and a plastic substrate.
